(19) United States
(12) Patent Application Publication
(10) Pub. No.: US 2012/0106157 A1
(43) Pub. Date: May 3, 2012

(54) MECHANISMS FOR REDUCING RISK OF SHOCK DURING INSTALLATION OF LIGHT TUBE

(75) Inventors: David Simon, Grosse Pointe Woods, MI (US); John Ivey, Farmington Hills, MI (US); Philip Kosarek, Shelby Township, MI (US); Craig Mackiewicz, Clawson, MI (US)

(73) Assignee: ALTAIR ENGINEERING, INC., Troy, MI (US)

(21) Appl. No.: 13/284,008

(22) Filed: Oct. 28, 2011

Related U.S. Application Data
(60) Provisional application No. 61/407,962, filed on Oct. 29, 2010.

(51) Int. Cl. F21V 21/00; H05K 13/00

(52) U.S. Cl. 362/249.05; 362/249.02; 29/592.1

(57) ABSTRACT

Disclosed herein is an LED-based light for replacing a fluorescent bulb in a conventional fluorescent light fixture. The LED-based light includes a housing having a first end opposing a second end, a circuit board disposed within the housing and extending along a longitudinal axis of the housing, at least one LED mounted to the circuit board, at least one end cap disposed on one of the first and second ends of the housing, the end cap including a switch and at least one electrically conductive pin configured for physical and electrical connection to the light fixture; and circuitry configured to provide a current path between the at least one LED and the at least one electrically conductive pin, wherein the switch is configured to selectively disconnect the current path.

### CROSS REFERENCE TO RELATED APPLICATION

This application claims priority to U.S. Provisional Patent Application No. 61/407,962, filed Oct. 29, 2010, which is incorporated herein by reference in its entirety.

### TECHNICAL FIELD

The invention relates to a light emitting diode (LED) based light usable in a conventional fluorescent lighting fixture.

### BACKGROUND

Fluorescent tube lights are widely used in a variety of locations, such as schools and office buildings. Although conventional fluorescent bulbs have certain advantages over, for example, incandescent lights, they also pose certain disadvantages including, inter alia, disposal problems due to the presence of toxic materials within the glass tube.

LED-based tube lights, which can be used as one-for-one replacements for fluorescent tube lights, have appeared in recent years. One such LED-based replacement light includes LEDs mounted on an elongated circuit board in a semi-cylindrical housing. A U-shaped lens can snap onto the housing to cover and disperse light from the LEDs. The replacement light can include two end caps, where an end cap is dispersed at each longitudinal end of the tube. The end caps generally include a molded plastic cup-shaped body that slides over the end of the tube to secure the end cap to the tube. Additionally, each end cap can include one or more connector pins for electrically and/or mechanically connecting the replacement light with standard fluorescent fixtures. For example, many end caps carry two connector pins for compatibility with fixtures designed to receive standard-sized tubes, such as T5, T8, or T12 tubes.

### SUMMARY

Embodiments of an LED-based light for replacing a fluorescent bulb in a conventional fluorescent light fixture are disclosed herein. In one embodiment, the LED-based light includes a housing having a first end opposing a second end, a circuit board disposed within the housing and extending along a longitudinal axis of the housing, at least one LED mounted to the circuit board, and at least one end cap disposed on one of the first and second ends of the housing. The end cap includes at least one electrically conductive pin configured for physical and electrical connection to the light fixture. Circuitry is configured to provide a current path between the at least one LED and the at least one electrically conductive pin, and a switch included in the end cap is configured to selectively disconnect the current path.

In another embodiment, the LED-based light includes a housing having a first end opposing a second end, a circuit board disposed within the housing and extending along a longitudinal axis of the housing, at least one LED mounted to the circuit board, and at least one end cap disposed on one of the first and second ends of the housing. The end cap includes at least one electrically conductive pin configured for physical and electrical connection to the light fixture. A pin cover composed of an insulating material is adjacent to the first end and configured to selectively expose and substantially enclose the electrically conductive pin.

Embodiments of a method of installing an LED-based light into a conventional fluorescent light fixture, the LED-based light including a housing having a first end opposing a second end, at least one LED disposed within the housing, a first end cap disposed on the first end of the housing including at least one electrically conductive pin, a second end cap disposed on the second end of the housing including at least one electrically conductive pin, circuitry providing a current path between the first and second end cap's electrically conductive pins, and a switch, are also disclosed herein. The method includes engaging the switch in a first position to disconnect the current path, positioning the first and second end cap's at least one electrically conductive pin into the light fixture, and engaging the switch in a second position to connect the current path.

These and other embodiments will be described in additional detail below.

### BRIEF DESCRIPTION OF THE DRAWINGS

The description herein makes reference to the accompanying drawings wherein like reference numerals refer to like parts throughout the several views, and wherein:

FIG. 1 is a partial perspective view of a LED-based replacement light in accordance with a first embodiment of the invention;

FIG. 2 is a partial perspective view of a LED-based replacement light in accordance with a second embodiment of the invention;

FIGS. 3A and 3B are partial perspective views of a LED-based replacement light in accordance with a third embodiment of the invention;

FIG. 4 is a partial perspective view of a LED-based replacement light in accordance with a fourth embodiment of the invention;

FIG. 5 is a partial perspective view of a LED-based replacement light in accordance with a fifth embodiment of the invention;

FIG. 6 is a partial perspective view of a LED-based replacement light in accordance with a sixth embodiment of the invention;

FIG. 7 is a partial perspective view of a LED-based replacement light in accordance with a seventh embodiment of the invention;

FIG. 8 is a partial perspective view of a LED-based replacement light in accordance with an eighth embodiment of the invention;

FIG. 9 is a partial perspective view of a LED-based replacement light in accordance with a ninth embodiment of the invention;

FIG. 10 is a partial perspective view of a LED-based replacement light in accordance with a tenth embodiment of the invention;

FIGS. 11A, 11B and 11C are a partial perspective view of a LED-based replacement light and the internal circuitry located within the light in accordance with an eleventh embodiment of the invention;

FIG. 12 is a partial perspective view of a LED-based replacement light in accordance with a twelfth embodiment of the invention;

FIG. 13 is a partial perspective view of a LED-based replacement light in accordance with a thirteenth embodiment of the invention;

FIG. 14 is a partial perspective view of a LED-based replacement light in accordance with a fourteenth embodiment of the invention;

FIGS. 15A and 15B are a partial perspective view of a LED-based replacement light and a pin cover in accordance with a fifteenth embodiment of the invention;

FIGS. 16A and 16B are partial perspective views of a LED-based replacement light in accordance with a sixteenth embodiment of the invention;

FIG. 17 is a partial perspective view of a LED-based replacement light in accordance with a seventeenth embodiment of the invention;

FIGS. 18A and 18B are partial perspective views of a LED-based replacement light in accordance with an eighteenth third embodiment of the invention;

FIGS. 19A and 19B are partial perspective views of a LED-based replacement light in accordance with a nineteenth embodiment of the invention;

FIGS. 20A and 20B are partial perspective views of a LED-based replacement light in accordance with a twentieth embodiment of the invention;

FIG. 21 is a partial perspective view of a LED-based replacement light in accordance with a twenty-first embodiment of the invention;

FIG. 22 is a partial perspective view of a LED-based replacement light in accordance with a twenty-second embodiment of the invention;

FIG. 23 is a cross-sectional view of an end cap for a LED-based replacement light in accordance with a twenty-third embodiment of the invention;

FIG. 24 is another cross-sectional view of the end cap of FIG. 23; and

FIG. 25 is an end view of the end cap of FIG. 23.

### DETAILED DESCRIPTION OF EMBODIMENTS OF THE INVENTION

One problem when replacing a fluorescent lamp with a LED-based replacement light is the potential for contact with the exposed connector pins during, for example, installation or relamping. Some lamps, such as fluorescent lamps and their replacements, are automatically prepared to conduct upon installation. Accordingly, if the lighting fixture is energized when one end of the lamp is plugged into the fixture, it is possible that electrical current may flow through the body of the person installing the lamp to ground. Specifically, if one or more pins are exposed while at least one other pin is in electrical contact with the fixture, the person may experience electrical shock if they come in contact with the pins.

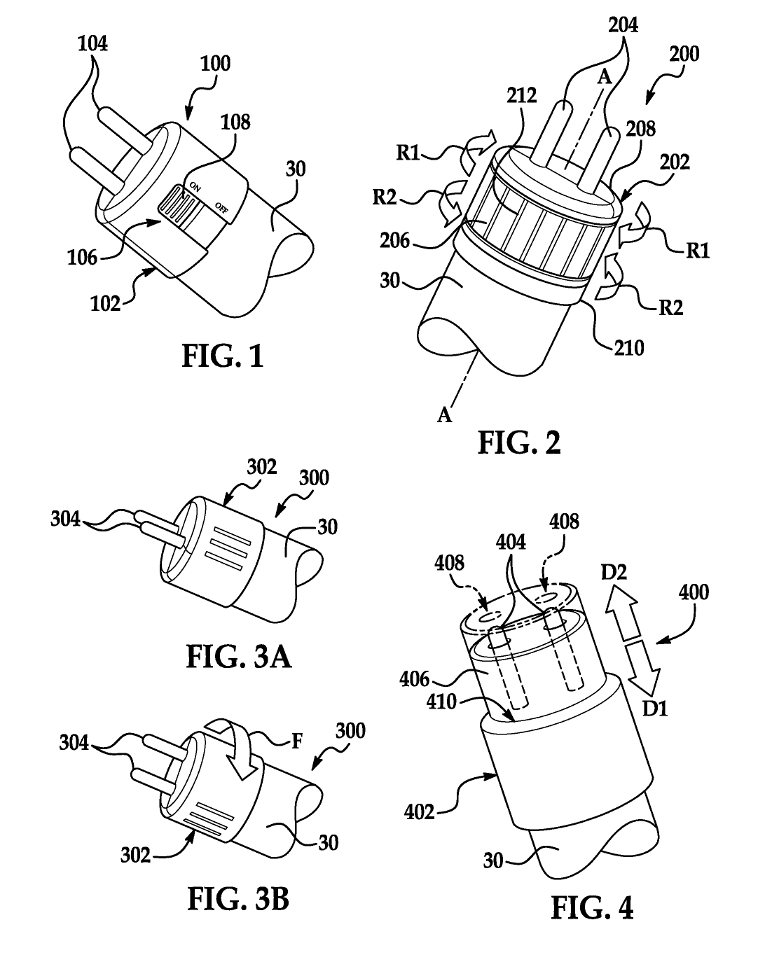

Embodiments of the present invention reduce or eliminate the shock hazard potential present in LED-based lights having exposed connector pins. FIGS. 1-25 illustrate these embodiments, which are LED-based replacement lights for replacing a conventional fluorescent light bulb in a fluorescent light fixture (not shown). The light fixture can be designed to accept standard fluorescent tubes, such as a T5, T8, or T12 fluorescent tube, or other standard sized lights, such as incandescent bulbs. Alternatively, the fixture can be designed to accept non-standard sized lights, such as lights installed by an electrician.

Each of the disclosed embodiments generally includes a circuit board (not shown), multiple LEDs (not shown) and a housing 30 at least partially defined by a high-dielectric translucent portion. The disclosed embodiments further include a pair of end caps with associated connector pins, which will be discussed in detail below.

The housing 30, as shown in the embodiments of FIGS. 1-22, is a light transmitting cylindrical tube. The housing 30 can be made from polycarbonate, acrylic, glass or another light transmitting material (i.e., the housing 30 can be transparent or translucent). For example, a translucent housing 30 can be made from a composite, such as polycarbonate with particles of a light refracting material interspersed in the polycarbonate. While the illustrated housing 30 is cylindrical, housings having a square, triangular, polygonal, or other cross sectional shape can alternatively be used. Similarly, while the illustrated housing 30 is linear, housings having an alternative shape, e.g., a U-shape or a circular shape can alternatively be used. Additionally, the housing 30 need not be a single piece. Instead, the housing 30 can be formed by attaching multiple individual parts, not all of which need be light transmitting. For example, a housing 30 can include an opaque lower portion and a lens or other transparent cover attached to the lower portion to cover the LEDs. The housing 30 can be manufactured to include light diffusing or refracting properties, such as by surface roughening or applying a diffusing film to the housing 30. For compatibility with the light fixture as discussed above, the housing 30 can have any suitable length. For example, the light may be approximately 48″ long, and the housing 30 can have a 0.625″, 1.0″, or 1.5″ diameter. The circuit board can be an elongated printed circuit board. Multiple circuit board sections can be joined by bridge connectors to create the circuit board. The circuit board can be slidably engaged with the housing 30, though the circuit board can alternatively be clipped, adhered, snap- or friction-fit, screwed or otherwise connected to the housing 30. For example, the circuit board can be mounted on a heat sink that is attached to the housing 30. Also, any other type of circuit board may be used, such as a metal core circuit board. Alternatively, instead of a circuit board, other types of electrical connections (e.g., wires) can be used to electrically connect the LEDs to a power source.

The LEDs can be surface-mount devices of a type available from Nichia, though other types of LEDs can alternatively be used. For example, one or more organic LEDs can be used in place of or in addition to the surface-mount LEDs. The LEDs can be mounted to the circuit board by solder, a snap-fit connection, or other means. The LEDs can produce white light. However, LEDs that produce blue light, ultra-violet light or other wavelengths of light can be used in place of white light emitting LEDs.

The number of LEDs can be a function of the desired power of the light and the power of the LEDs. For a 48″ light, for example, the number of LEDs can vary from about five to four hundred such that the light outputs approximately 500 to 3,000 lumens. However, a different number of LEDs can alternatively be used, and the light can output a different amount of lumens. The LEDs can be evenly spaced along the circuit board, and the spacing of the LEDs can be determined based on, for example, the light distribution of each LED and the number of LEDs. Alternatively, a single or multiple LEDs can be located at one or both ends of the light.

While the light can be compatible with standard sized fluorescent fixtures, an LED-based light having another shape, such as an incandescent bulb or another type of light, can alternatively be used. Also, other types of light sources, such as fluorescent or incandescent based light sources, can be used instead of or in addition to the LEDs.

FIG. 1 illustrates a light 100 in accordance with a first embodiment of the present invention. The light 100 can include two end caps 102 (only one end cap is shown in FIG. 1) with each end cap 102 carrying two electrically conductive pins 104 (i.e. bi-pin end caps). The pins 104 can be made of any type of electrically conductive material such as copper, aluminum, or other types of conductors. Each end cap 102 is located at a longitudinal end of the housing 30 for physically and electrically connecting the light 100 to the fixture. The end caps 102 can be made of any suitable material such as thermoplastic, thermoset or other types of insulators.

The end caps 102 can be the sole physical connection between the light 100 and the fixture. The end caps 102 can also be electrically connected to the circuit board to provide power to the LEDs. Although each end cap 102 is shown as including two pins 104, one or two of the total four pins that are located on both ends of the housing 30 can be “dummy pins” that do not provide an electrical connection. Alternatively, other types of electrical connectors can be used, such as an end cap carrying a single pin. Also, while the end caps 102 are shown as including cup-shaped bodies, the end caps 102 can have a different configuration (e.g., the end caps 102 can be shaped to be press fit into the housing 30). One or both of the end caps 102 can additionally include electric components, such as a rectifier and filter.

Circuitry can provide a current path in the light 100. The current path can be between the ends of the light 100, for example between one or more pins 104 of the end caps 102. The current path can include one or more pins 104 of the end cap 102, LEDs, the circuit board or wires, or any suitable combination thereof. For example, the current path can be between a pin 104 and the LEDs, between a pin 104 and the circuit board, or between the LEDs and the circuit board. One or both of the end caps 102 include a switch 106 that can selectively disconnect the current path. The switch 106 includes a sliding button 108 that can be selectively engaged between an “ON” position and an “OFF” position. The current path is disconnected when the button 108 is slid into the “OFF” position and is connected when the button 108 is slid into the “ON” position. Before the light 100 is installed in a light fixture, the switch 106 can be set (e.g., by the manufacturer or the installer) to the “OFF” position such that an open circuit condition exists, for example, between the ends of the tube. While the switch 106 is shown as a manual slide switch, any other suitable switch may be used. For example, in some embodiments the switch may be a push-button switch or a toggle switch. Additionally, the switch 106 may be labeled to warn the user not to energize the lamp (i.e. set the switch to “ON”) until the lamp is fully installed. The label may be placed such that it must be removed before energizing the switch.

The switch 106 can break a current path at any point in the circuitry of the light 100. For example, one end of the switch 106 can be connected to the pins 104 of one of the end caps 102 and the other end of the switch 106 can be connected to the circuit board. Accordingly, when the switch 106 is in the “OFF” position, there will be no current flowing from the circuit board to the pins 104 and vice versa. However, the switch can be connected in any suitable manner to create the open circuit condition within light 100. As one example, the switch can break the current path between two series-connected LEDs.

When the installer places one end of the tube into an energized fixture and when the switch 106 is in the “OFF” position, the installer can remove or reduce the risk of shock if he comes into contact with the pins 104 by ensuring that the button 108 of the switch 106 is in the “OFF” position. Accordingly, as discussed previously, there will be no current flowing to the pins 104. Once the installer places both ends of the tube into the fixtures, the installer can then move the switch 106 from “OFF” to “ON” thereby reestablishing a closed circuit connection between the ends of the tube (i.e. permitting current to flow through light 100). Likewise, when the installer decides that he would like to remove the light 100 from the fixture, the installer can move the switch from the “ON” to “OFF” position to establish the open circuit connection.

FIG. 2 illustrates a light 200 in accordance with a second embodiment of the present invention. The light 200 can include, similar to the first embodiment, two end caps 202 (only one end cap shown in FIG. 2) with each end cap 202 carrying two pins 204. One or both of the end caps 202 enable a feature similar to that described in connection with the first embodiment illustrated in FIG. 1. Specifically, the installer can break the current path at a point in the circuitry while the light is being installed or removed from the light fixture. However, rather than including the switch 106, the light 200 includes a rotatable collar 206 to actuate an internal switch (not shown) connected within the electrical circuitry of the light 200. The collar 206 can be rotatable about an axis A-A of the light 200. The collar 206 is rotated about the axis A-A in a first clockwise direction R1 to an “ON” position to actuate the switch and to create the closed circuit connection, where current can flow to the pins 204. The collar 206 can be rotated in a second counterclockwise direction R2 to an “OFF” position such that an open circuit condition exists and current no longer flows to the pins 204. Alternatively, in another embodiment the collar 206 can be rotated in the first direction R1 to an “OFF” position and rotated in second direction R2 to an “ON” position if desired.

The collar 206 circumferentially extends around and is rotatable about the end cap 202. Although the collar 206 is shown in FIG. 2 as extending from just below a top end 208 of end cap 202 to just above a bottom end 210 of end cap 202, the collar may be located in a different position as well. For example, the collar can be limited to a portion of the mid-section of the end cap 202.

The collar 206 also includes an outer knurled surface 212. Alternatively, the collar 206 may include another suitable gripping contour, or may not include any gripping contour at all. In other embodiments, the collar may include a protrusion that aids a user in grasping the collar. The protrusion may be used in conjunction with an “ON” indicator for signifying when the switch has been actuated and an “OFF” indicator for signifying when the switch has not been actuated.

Similar to the first embodiment, when the installer places one end of the tube 30 into an energized fixture, the installer can remove or reduce the risk of shock if he comes into contact with the pins 204 by rotating the collar 206 after both ends of the light 200 have been placed into the fixture.

FIGS. 3A and 3B illustrate a light 300 in accordance with a third embodiment of the present invention. The light 300 can include, similar to the first and second embodiments, two end caps 302 (only one end cap shown in FIGS. 3A and 3B) with each end cap 302 carrying two pins 304. One or both of end caps 302 enable a feature similar to that described in connection with the first and second embodiments illustrated in FIGS. 1 and 2, respectively. Specifically, the installer can break the current path in the light 300 at a point in the circuitry while the light is being installed or removed from the light fixture. However, rather than including the switch 106 or the collar 206, one or both end caps 302 can be rotated relative to housing 30 by a rotational force F exerted on the end cap 302 and/or the housing 30.

FIG. 3A illustrates the end cap 302 and pins 304 in a first position, before the end cap 302 and the pins 304 have been rotated. When in the first position as shown in FIG. 3A, the open circuit condition is created. To permit electrical current to flow through both ends of the tube, as illustrated in FIG. 3B, the end cap 302 can be rotated to a second position. The end cap 302 may be rotated about 90 degrees to the second position such that an internal switch (not shown) closes within the electrical circuitry of light 300. Of course, the end cap 302 can be rotated to any other suitable degree (e.g., 180 degrees). The end cap 302 also includes a retaining feature (not shown) that holds the end cap 302 in the “ON” position, where the retaining feature can be any device that secures the end cap 302 in the second position. As one example, the retaining feature is a biasing device that exerts a spring force to hold the end cap 302 in the second position.

FIG. 4 illustrates a light 400 in accordance with a fourth embodiment of the present invention. The light 400 can include two end caps 402 (only one end cap shown in FIG. 4) with each end cap 402 carrying two pins 404. Each end cap 402 is at a longitudinal end of the housing 30, for physically and electrically connecting the light 400 to the fixture.

The light 400 also includes a pin cover 406 constructed from an insulating material such as, for example, a thermoplastic. As illustrated, the cover 406 has a cylindrical shape and is concentric with the housing 30 and the end cap 402. The cover 406 has an outer diameter that is slightly smaller than the outer diameter of housing 30. However, the pin cover can also include a number of different shapes and sizes to cover pins 404.

The cover 406 can be attached to a spring or other type of biasing mechanism (not shown) located within the tube 30, and allows the cover 406 to retract into the end cap 402 in a first direction D1 when a force is exerted, and correspondingly allows the cover 406 to travel in a second direction D2 to a protracted position (illustrated in phantom line) when the force is no longer applied to the end cap 402. The cover 406, when in the protracted position, covers the pins 406 before the light 400 is installed. The cover 406 can telescope within the end cap 402 during installation. Specifically, when the installer installs one of the ends of the light tube 400 into the fixture, the force exerted by pressing the respective end of the light tube 400 into the fixture urges the cover 406 in the first direction D1 which axially retracts the pin cover 406 into the end cap 402.

Accordingly, after a force has been applied to the cover 406, the pins 404 can be exposed through apertures 408 in the cover 406. The apertures 408 can be sized to pass the pins 404, but can be sized to not permit other objects to pass. For example, the apertures can have a 0.25″ diameter such that the installer's fingers or tools cannot pass through. It follows that the cover 406 protects the installer from coming into contact with the pins 404 and can avoid any possible electrical shock.

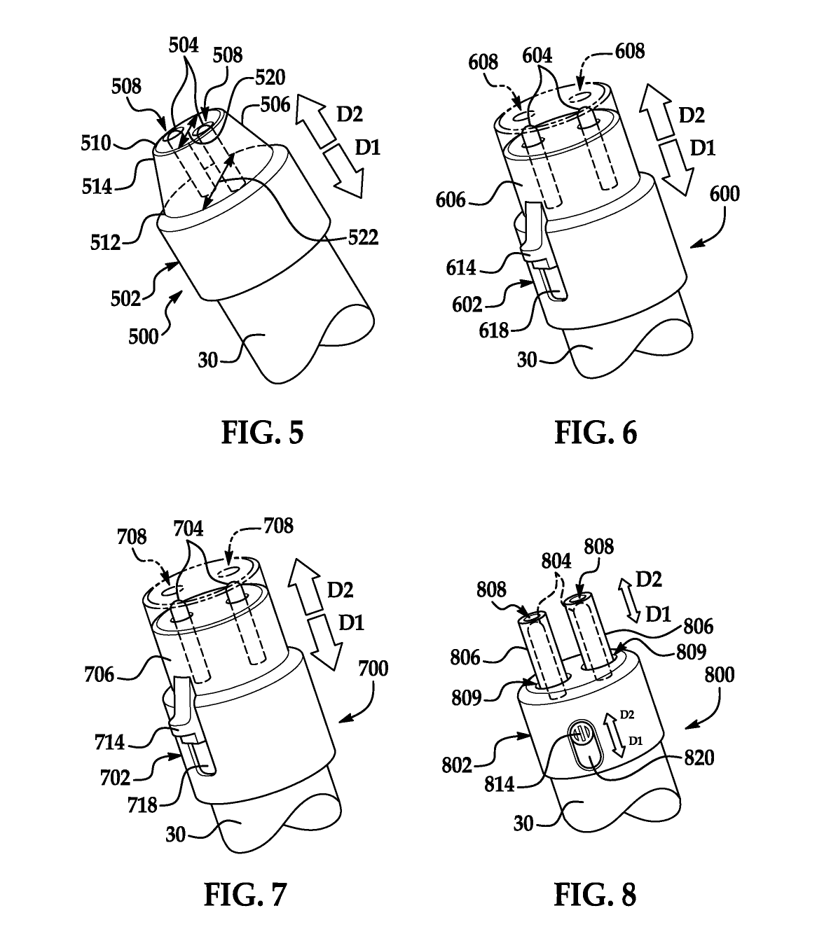

FIG. 5 illustrates a light 500 in accordance with a fifth embodiment of the present invention. The light 500 can include, similar to the fourth embodiment, two end caps 502 (only one end cap shown in FIG. 5) with each end cap 502 carrying two pins 504, and a pin cover 506. Like the fourth embodiment, the pin cover 506 has two apertures 508. The cover 506 covers the pins before installation and is able to telescope within end cap 502 when a force is exerted by the installer during installation. However, unlike the fourth embodiment, the pin cover 506 is tapered, where a first end 510 of the cover 506 gradually and outwardly ramps to a second end 512. In other words, as illustrated in FIG. 5, a first diameter 520 of the first end 510 is smaller than a second diameter 522 of the second end 512. The radial insertion of the light 500 into the fixture causes the cover 506 to press against an end of the fixture, thereby urging the cover 506 to retract within the end cap 502.

Similar to the fourth embodiment, the cover 506 is attached to a spring or biasing element (not shown) that causes the pin cover 506 to retract, as discussed previously. Specifically, the end cap 502 is retractable in a first direction D1 when a force is exerted, and the cover 506 travels in a second direction D2 to a protracted position when the force is no longer applied to the end cap 502. The pins 504 can be exposed through apertures 508 in the cover 506, where the apertures 508 are sized to pass the pins 504, but can be sized not to permit other objects to pass. It follows that the cover 506 protects the installer from coming into contact with the pins 504 and can avoid any possible electrical shock.

FIG. 6 illustrates a light 600 in accordance with a sixth embodiment of the present invention. The light 600 can include, similar to the fourth embodiment, two end caps 602 (only one end cap shown in FIG. 6) with each end cap 602 carrying two pins 604 and a pin cover 606. Like the fourth embodiment, the pin cover 606 has two apertures 608. The pin cover 606 has a cylindrical shape and is concentric with the housing 30 and the end cap 602. The cover 606 covers the pins 604 before installation and telescopes within the end cap 602 when a force is exerted by the installer during installation. However, unlike the fourth embodiment, a manual slide lever 614 is included and is slidable within a groove 618, which enables the cover 606 to move within the end cap 602 in the first direction D1 and the second direction D2.

The lever 614 can be attached either directly or indirectly to the cover 606 such that when the lever 614 is moved in the first direction D1, the lever 614 forces the cover 606 to retract into the end cap 602. When the lever 614 is moved in the second direction D2, the lever 614 urges the cover 606 out of the end cap 602, causing the cover 606 to protract. The lever 614 can be located in a position relative to the pins 604 such that the installer's fingers are unlikely to come in contact with the pins 604 when the cover 606 is retracted. In alternative embodiments, a button, knob or other suitable device can be used in lieu of lever 614.

FIG. 7 illustrates a light 700 in accordance with a seventh embodiment of the present invention. The light 700 can include, similar to the sixth embodiment, two end caps 702 (only one end cap shown in FIG. 7) with each end cap 702 carrying two pins 704 and a pin cover 706 having two apertures 708. Like the sixth embodiment, the cover 706 covers the pins before installation and telescopes within the end cap 702 using a manual slide lever 714 that is slidable within a groove 718. The lever 714 allows the cover 706 to move within the end cap 702 in the first direction D1 and the second direction D2. However, unlike the sixth embodiment, the lever 714 can include a locking mechanism (not shown) that can prevent or permit retraction of the cover 706.

For example, the locking mechanism can prevent the cover 706 from retracting into the end cap 702 when the locking mechanism is in a locked (i.e. latched) position. The locking mechanism can be locked or latched when, for example, there is no force exerted to inwardly press the lever 714 (i.e. by the installer). The locking mechanism permits the cover 706 to retract into the end cap 702 when the locking mechanism is in an unlocked (i.e. unlatched) position. The locking mechanism can be unlocked or unlatched, when, for example, the installer exerts a force to inwardly press the lever 714. The locking mechanism is any type of device that can selectively prevent the lever 714 from sliding within the groove 718, and can include a variety of mechanisms such as, for example, a latch, a pin, or a spring (all not shown).

In one embodiment of the locking mechanism, when the cover 706 is in the protracted position and the locking mechanism is in the latched position, the locking mechanism includes a spring and a pin that can engage with a latch. To remove the pin from the latch, the installer can inwardly press and hold the lever 714, which causes the locking mechanism to release the pin. Accordingly, the installer can (while simultaneously pressing the lever 714), move the lever 714 in the first direction D1, which permits the cover 706 to retract within end cap 702 or within the second direction D2, which permits the cover 706 to protract from within end cap 702. Of course, other locking mechanisms are available that can be used instead of or in addition to the locking mechanism described above.

FIG. 8 illustrates a light 800 in accordance with an eighth embodiment of the present invention. The light 800 can include, similar to the sixth embodiment, two end caps 802 (only one end cap shown in FIG. 8). Each end cap 802 has two pins 804 extending therethrough. Unlike the sixth embodiment where the cover 606 is concentric with, for example, the tube 30, the light 800 includes and a separate pin cover 806 for each pin 804. Each pin cover 806 covers the pins 804 before instillation. In this embodiment, however, each pin cover 806 can telescope within a respective aperture of 809 of end cap 802 when a force is exerted by the installer during installation.

A manual slide button 814 slidable within a groove 820 enables the pin covers 806 to protract and retract into the end cap 802. Similar to the sixth embodiment, the button 814 can be engaged directly or indirectly with covers 806 such that when the button 814 is moved in the first direction D1 the covers 806 retract into the end cap 802. When the button 814 is moved in the second direction D2, the covers 806 protract from the end cap 802.

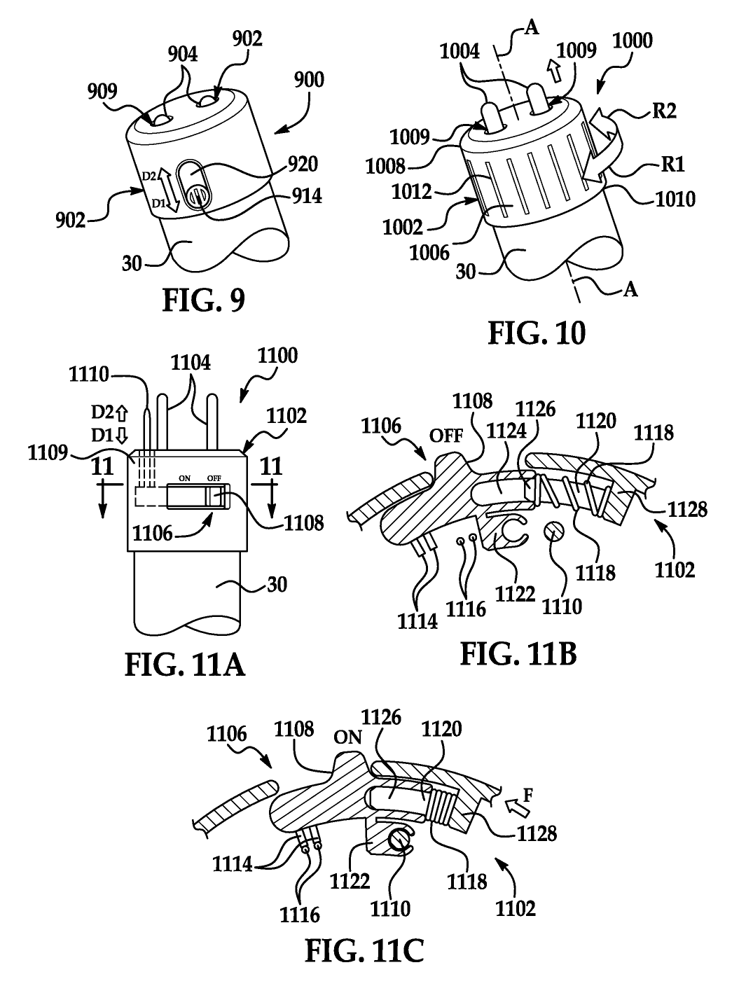

FIG. 9 illustrates a light 900 in accordance with a ninth embodiment of the present invention. The light 900 can include, similar to the eighth embodiment, two end caps 902 (only one end cap shown in FIG. 9). Each end cap 902 has two pins 904 extending therethrough. FIG. 9 illustrates the pins 904 retracted into a respective aperture 909 of the end cap 902. Unlike the eighth embodiment, which includes pin covers 806, the light 900 includes an extension mechanism (not shown) which causes the pins 904 protract and retract into the respective aperture 909. In one embodiment, at least a portion of the aperture 909 where the pins 904 retract into is constructed of a dielectric material, however, other types material can be used as well.

A manual slide button 914 slidable within a groove 920 enables the pins 904 to protract and retract. The button 914 can be engaged directly or indirectly with pins 904 such that when the button 914 is moved in the first direction D1, the pins 904 retract into the end cap 902, and when the button 914 is moved in the second direction D2 the pins 904 protract from the end cap 902. The pins 904 can be in the retracted position when received by the manufacturer, or can be moved into the retracted position before installation into a lighting fixture by an installer. When the installer installs one or both the ends of the light tube 900 into the fixture, the installer can move the manual slide button 914 to the second position D2, thereby protracting the pins 904 from the end cap 902. Once the pins 904 have been protracted from the end cap 902 and are exposed, the pins 904 can be in electrical communication with the lighting fixture. Similarly, when the installer wants to remove the light tube 900, the button 914 is moved in the first direction D1 to retract the pins 904 before removing the light tube 900 from the fixture. Although a manual slide button is illustrated, a different device (e.g. manual slide lever) may be used as well. Alternatively, a spring-loaded device including an elastic element may be used instead to protract or retract the pins.

FIG. 10 illustrates a light 1000 in accordance with a tenth embodiment of the present invention. The light 1000 can include, similar to the eighth and ninth embodiments, two end caps 1002 (only one end cap shown in FIG. 10). Each end cap 1002 can have two pins 1004 extending therethrough. Instead of a slide lever or button as described in previous embodiments, the light 100 includes a rotatable collar 1006 that is generally circular for protracting and retracting pins 1004 into respective apertures 1009. The collar 1006 circumferentially extends around and is rotatable about the end cap 1002. Although the collar 1006 is shown in FIG. 10 as extending from just below a top end 1008 of the end cap 1002 to just above a bottom end 1010 of the end cap 1002, the collar 1006 may be located in a different position as well. For example, the collar can be limited to a portion of the mid-section of the end cap 1002. In another embodiment, the collar 1006 is integrated with the end cap 1002.

The collar 1006 also includes an outer knurled surface 1012. Alternatively, the collar 1006 may include another suitable gripping contour, or may not include any gripping contour at all. In other embodiments, the collar may include a protrusion that aids a user in grasping the collar 1006.

The collar 1006 is rotatable about a longitudinal axis A-A of the light 1000. The collar 1006 is rotated about the axis A-A in a first clockwise direction R1 permitting the pins 1004 to protract from the respective aperture 1009 of the end cap 1002. When the collar 1006 is rotated in a second counterclockwise direction R2 the pins 1004 can be retracted in the respective apertures 1009 of the end cap 1002. Alternatively, in another embodiment the collar 1006 can be rotated in the first direction R1 to retract the pins 1004 and rotated in the second direction R2 to protract the pins 1004 if desired.

FIGS. 11A-11C illustrate a light 1100 in accordance with an eleventh embodiment of the present invention. Referring to FIG. 11A, the light 1100 can include two end caps 1102 (only one end cap shown in FIG. 11). Each end cap 1102 has two pins 1104 extending therethrough. One or both of the end caps 1102 include a feature where the installer can break the current path at a point in the circuitry while the light 1100 is being installed or removed from the light fixture. One or both of the end caps 1102 include a switch 1106 that cooperates with a moveable pin 1110 for connecting and disconnecting a current path between the ends of the light 1100. The switch 1106 includes a sliding button 1108 that can be slid between an “ON” position and an “OFF” position. The moveable pin 1110 is spring loaded by a biasing mechanism such as, for example, a coil spring. The moveable pin 1110 can be selectively protracted from and retracted into an aperture 1109 of the end cap 1102.

The current path is disconnected when the button 1108 is slid into the “OFF” position and/or the moveable pin 1110 is urged into the second direction D2, where the moveable pin 1110 is protracted from the aperture 1109 of the end cap 1102. The current path is connected when the button 1108 is slid into the “ON” position and the moveable pin 1110 is urged into the first direction D1, where the moveable pin 1110 is retracted into the aperture 1109 of the end cap 1102.

FIGS. 11B and 11C are a cross sectional view of the internal components located in the end cap 1102 for breaking the current path, where FIG. 11B is an illustration of the circuitry in the “OFF” position and FIG. 11C is an illustration in the “ON” position. The button 1108 includes one or more moveable contacts 1114 that are located within an interior of the end cap 1102 and can be brought into sliding contact with a set of stationary contacts 1116 for closing the circuit path. The sliding button 1108 includes an aperture 1124 for receiving a spring loaded pin 1120. The pin 1120 includes a biasing mechanism such as a coil spring 1118. The sliding button 1108 includes an aperture 1124 for receiving a first end 1126 of the pin 1120 and a latching mechanism 1122. The pin 1120 includes a second end 1128 that is connected to the end cap 1102. The latching mechanism 1122 is a generally hook-shaped member, however the latching mechanism 1122 can be any mechanism suitable for engagement with the moveable pin 1110.

Referring to FIGS. 11A-11C, before the lamp 1100 is installed, the button 1108 is in the “OFF” position and the latching mechanism 1122 is not connected to the moveable pin 1110. When the installer places an end of the light 1100 into an energized fixture, the moveable pin 1110 contacts a fixture connector such that the moveable pin 1110 is depressed in the first direction D1 into the aperture 1109 of the end cap 1102. The installer slides the button 1108 to the “ON” position, thereby compressing the spring 1118 and the moveable pin 1110 engages with the latching mechanism 1122. The contacts 1114 located on the button 1108 are brought into contact with the stationary contacts 1116, thereby closing the circuit, and allowing current to flow to the pins 1104. When the lamp 1100 is removed from the fixture, the moveable pin 1110 protracts from the end cap 1102 and disengages from the latching mechanism 1122. The button 1108 is urged into the “OFF” position by a biasing force F exerted by the compressed spring 1118, and the contacts 1114 and 1116 are no longer in electrical communication with one another, thereby opening the circuit.

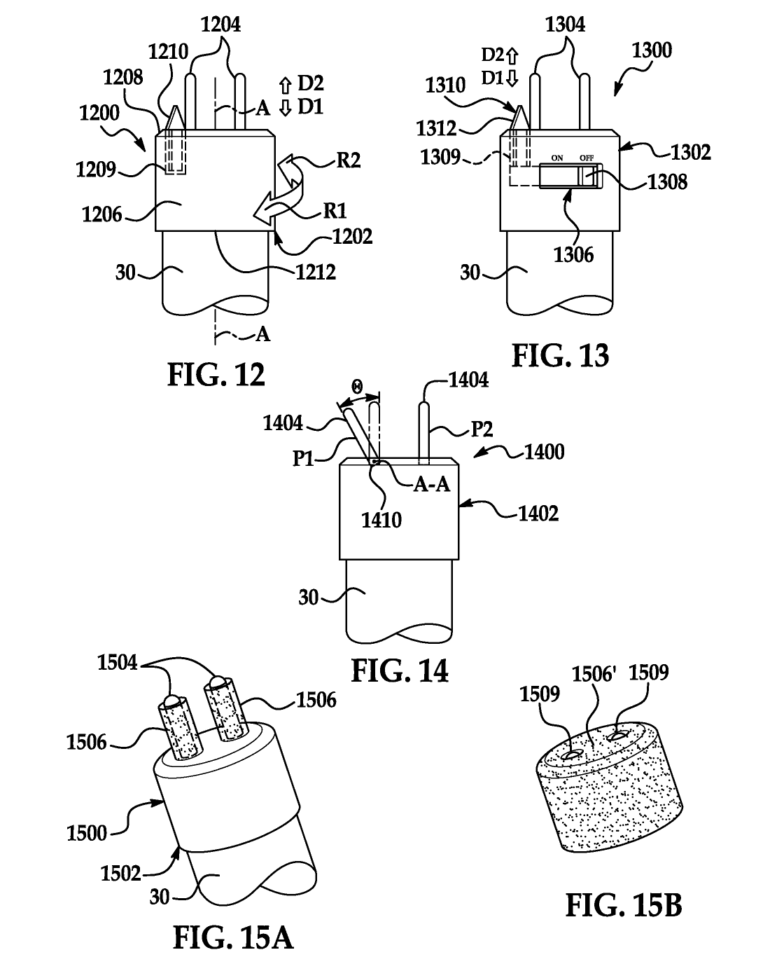

FIG. 12 illustrates a light 1200 in accordance with a twelfth embodiment of the present invention. The light 1200 can include, similar to the eleventh embodiment, two end caps 1202 (only one end cap shown in FIG. 12). Each end cap 1202 can have two pins 1204 extending therethrough, and a moveable pin 1210, and includes similar internal circuitry illustrated in FIGS. 11B-11C. However, instead of a slide lever or button as described in previous embodiments, the light 1200 includes a rotatable collar 1206 of circular shape for protracting and retracting the moveable pin 1210 into a respective aperture 1209. The collar 1206 circumferentially extends around and is rotatable about the end cap 1202. Although the collar 1206 is shown in FIG. 12 as extending from just below a top end 1208 of the end cap 1202 to just above a bottom end 1212 of the end cap 1202, the collar 1206 may be located in a different position as well. For example, the collar can be limited to a portion of the mid-section of the end cap 1202. In another embodiment, the collar 1206 is integrated with the end cap 1202.

Although not illustrated, the collar 1206 may include an outer knurled surface that provides a textured surface that is easier for a user to grasp. Alternatively, another suitable gripping contour may be provided as well. The collar 1206 is rotatable about a longitudinal axis A-A of the light 1200. The collar 1206, instead of sliding button 1108 illustrated in the eleventh embodiment, acts as a switch to move the internal circuitry of the light 1200 between an “ON” position and an “OFF” position. The collar 1206 is rotated about the axis A-A in a first clockwise direction R1 to the “ON” position and is rotated in a second counterclockwise direction R2 to the “OFF” position. Alternatively, in another embodiment the collar 1206 can be rotated in the first direction R1 to the “OFF” position and rotated in the second direction R2 to the “ON” position if desired.

When the installer places an end of the light 1200 into an energized fixture, the moveable pin 1210 contacts a fixture connector such that the moveable pin 1210 is depressed in the first direction D1 into the aperture 1209 of the end cap 1202. Similar to the eleventh embodiment illustrated in FIGS. 11B-11C, the moveable pin 1210 engages with a latching mechanism located within an interior of the end cap 1202. The installer then rotates the collar 1206 to the “ON” position. The internal circuitry of the light 1200 is then closed, allowing current to flow to the pins 1204. When the lamp 1200 is removed from the fixture, the moveable pin 1210 protracts from the end cap 1102 and disengages from the latching mechanism. The collar 1206 may be rotated about the axis A-A to the “OFF” position by a biasing force exerted by a spring located within the end cap 1202 (similar to the spring 1118 illustrated in FIGS. 11B-11C), thereby opening the circuit.

FIG. 13 illustrates a light 1300 in accordance with a thirteenth embodiment of the present invention. The light 1300 can include, similar to the eleventh embodiment, two end caps 1302 (only one end cap shown in FIG. 13). Each end cap 1302 can have two pins 1304 extending therethrough and a moveable pin 1310. The light 1300 includes a feature similar to the embodiment illustrated in FIGS. 11A-11C where the installer can break the current path at a point in the circuitry, and includes a switch 1306 that cooperates with the moveable pin 1310 for selectively disconnecting a current path between the ends of the light 1300. The switch 1306 includes a sliding button 1308 that can be slid between an “ON” position and an “OFF” position, and the moveable pin 1310 can be selectively protracted from and retracted into an aperture 1309 of the end cap 1302. However, unlike the eleventh embodiment, the moveable pin 1310 includes an outer surface 1312 with sloped or ramped sides to facilitate placing the moveable pin 1310 into the aperture 1309. Specifically, the sloped outer surface 1312 provides more surface area contact with the lighting fixture than a straight pin, especially when the light 1300 is installed at an angle.

The exposed portion of the outer surface 1312 of the moveable pin 1310 includes a generally triangular or pointed profile when protracted from the end cap 1302. When the installer places an end of the light 1300 into an energized fixture, the sloped outer surface 1312 of the moveable pin 1310 contacts a fixture connector such that the moveable pin 1310 is depressed in the first direction D1 and into the aperture 1309 of the end cap 1302, thereby closing the circuitry located within the light 1300. When the lamp 1300 is removed from the fixture, the moveable pin 1310 protracts from the end cap 1302 in the second direction, thereby opening the circuit.

FIG. 14 illustrates a light 1400 in accordance with a fourteenth embodiment of the present invention. The light 1400 can include two end caps 1402 (only one end cap shown in FIG. 14) with each end cap 1402 carrying two pins 1404. One or both the pins 1404 are rotatable about an axis A-A between a first position P1 (shown on the left pin 1404) and a second position P2 (shown on the right pin 1404). The pin 1404 is rotatable about the axis A-A at a predetermined angle θ. As illustrated in FIG. 14 the angle θ is about 30 degrees, however it is understood that the angle θ may be any other suitable angle (e.g., 15 degrees).

When in the first position P1, an open circuit condition is created. The pin 1404 can be rotated about the axis A-A to the second position P2 to close the circuit, thereby allowing current to flow to the pin 1404. Specifically, a bottom end 1410 of the pin 1404 contacts an electrical contact (not shown) located in the end cap 1402 when the pin 1404 is upright and in the second position P2, thereby allowing current to flow in the light 1400. When the pin 1404 is rotated about the axis A-A to the first position P1, the bottom end 1410 of the pin 1404 moves away from and no longer makes contact with the electrical contact, thereby opening the circuit. Although an electrical contact is discussed, the bottom end 1410 of the pin 1404 may also contact a switch actuator to open and close the circuitry of the light 1400 as well.

At least one of the pins 1404 is set to the first position P1 when the installer places an end of the light 1400 into an energized fixture. The fixture connector makes contact with the pin 1404 such that the pin 1404 rotates about the axis A-A at the angle θ and into the second position P2, which closes the circuitry located within the light 1400 and allowing current to flow to the pins 1404. The lighting fixture holds the pins 1404 upright in the second position P2 until the light 1400 is removed from the fixture. When removed from the fixture, the pins 1404 rotate about the axis A-A back to the first position P1, where current can no longer flow to the pins 1404.

FIG. 15A illustrates a light 1500 in accordance with a fifteenth embodiment of the present invention. The light 1500 can include two end caps 1502 (only one end cap shown in FIG. 15) with each end cap 1502 carrying two pins 1504. The pins 1504 each include a corresponding pin cover 1506 constructed from a resilient electrically insulating material such as, for example, an expandable foam. However, any electrically insulating material that is resilient enough to compress when the pins 1504 are inserted into a light fixture may be used as well. As illustrated, each of the pin covers 1506 have a generally cylindrical shape and are concentric with the respective pin 1504. When the light 1500 is installed in the lighting fixture, the pin covers 1506 are compressed as the pins 1504 are axially inserted into the lighting fixture, revealing the pins 1504. When the light 1500 is removed from the lighting fixture, the pin covers 1504 expand to cover each of the pins 1504.

FIG. 15B is an alternative embodiment 1506′ of the pin cover. In the embodiment as illustrated, the pin cover 1506′ covers both of the pins 1504, and includes a generally cylindrical shape which is concentric with the housing 30 and the end cap 1502. The pin cover 1506′ also includes two apertures 1509 for receiving each of the pins 1504. Similar to the embodiment in FIG. 15A, when the light is installed into the lighting fixture, the entire pin cover 1506′ is compressed as the pins 1504 are axially inserted into the lighting fixture. The pin cover 1506′ expands back to cover the pins 1504 when the light 1500 is removed from the lighting fixture.

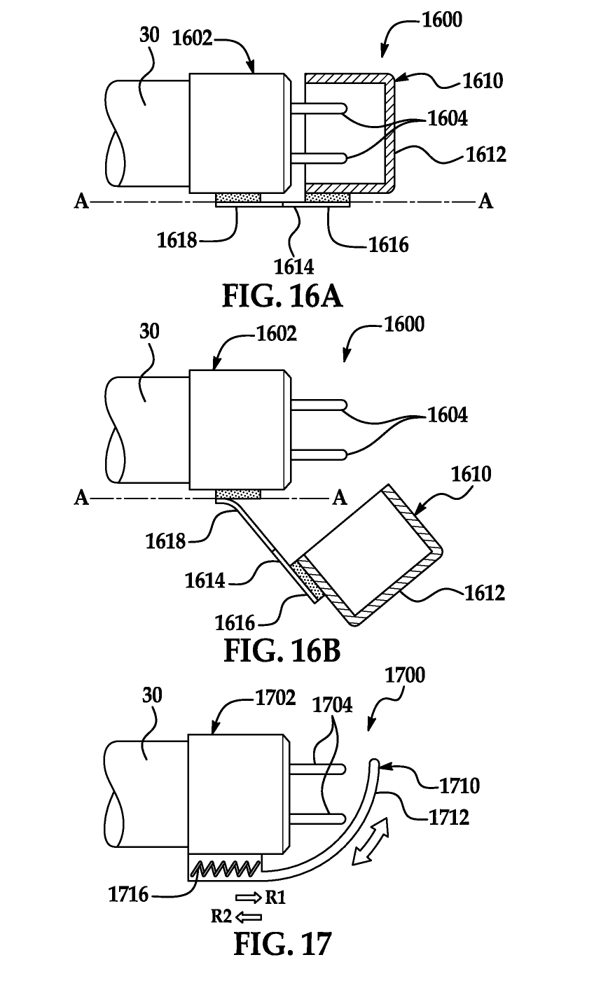

FIGS. 16A and 16B illustrate a light 1600 in accordance with a sixteenth embodiment of the present invention. The light 1600 can include, similar to the sixteenth embodiment, two end caps 1602 (only one end cap shown in FIG. 16). Each end cap 1602 has two pins 1604 extending therethrough. The light 1600 includes a covering assembly 1610 that covers the pins 1602, and is selectively rotatable about an end axis A-A end to reveal the pins 1604 when the light 1600 is placed in the lighting fixture.

The covering assembly 1610 includes a cover 1612 that is constructed from an insulating material such as, for example, a thermoplastic. The cover 1612 can be generally C-shaped to cover the pins 1602 and is held in place by a spring loaded connecting member 1614. The connecting member 1614 includes a first end 1616 and a second end 1618, where the connecting member 1614 is attached to the covering 1612 at the first end 1616 and to the end cap 1602 at the second end 1618. The connecting member 1614 is a spring loaded or other type of biased mechanism that rotates about the end axis A-A when the installer places the light tube 1600 into the fixture. Specifically, when the cover 1612 contacts the light fixture, the connecting member 1614 is rotated about the end axis A-A such that the connecting member 1614 springs into the position illustrated in FIG. 16B, thereby exposing the pins 1604. Once the pins 1604 are exposed, the pins 1604 can be in electrical communication with the lighting fixture. The lighting fixture can hold the cover 1612 in place to keep the pins 1604 exposed. Similarly, when the installer removes the light tube 1600, the connecting member 1614 is biased or spring loaded such that the connecting member 1614 springs back to the covered position as seen in FIG. 16A, as the lighting fixture no longer holds the cover 1612 in place.

FIG. 17 illustrates a light 1700 in accordance with a seventeenth embodiment of the present invention. The light 1700 can include, similar to the sixteenth embodiment, two end caps 1702 (only one end cap shown in FIG. 17). Each end cap 1702 can have two pins 1704 extending therethrough and a covering 1710. The light 1700 includes a feature similar to the embodiment illustrated in FIGS. 16A and 16B where the covering assembly 1710 exposes the pins 1704 when the light 1700 is installed. However, unlike the sixteenth embodiment, the covering assembly 1710 includes a cover 1712 constructed from a resilient material that is biased to selectively curve over the pins 1704, and is slidable axially to retract and reveal the pins 1704 when the light 1700 is removed from the fixture.

The covering assembly 1710 may also include a biasing member 1716 such as, for example, a spring that assists the cover 1712 in springing into a closed position to cover the pins 1704. Specifically, when the cover 1712 contacts the light fixture, the cover 1712 springs into a retracted position, thereby exposing the pins 1704. Once the pins 1704 are exposed, the pins 1704 can be in electrical communication with the lighting fixture. The lighting fixture can hold the cover 1712 in place to keep the pins 1704 exposed. Similarly, when the installer removes the light tube 1700, the connecting member 1716 is biased or spring loaded such that the connecting member 1716 springs back to cover the pins 1704, as the lighting fixture no longer holds the cover 1712 in place. The biasing member 1716 is biased in a direction R1, and provides a biasing force that assists the cover 1712 in springing back to a closed position to cover the pins 1704. Alternatively, in another embodiment, the biasing member 1716 is biased in a second direction R2 that is opposite the first direction R1. In this alternative embodiment, the biasing member 1716 assists the cover 1712 in springing to an open position to reveal the pins 1704.

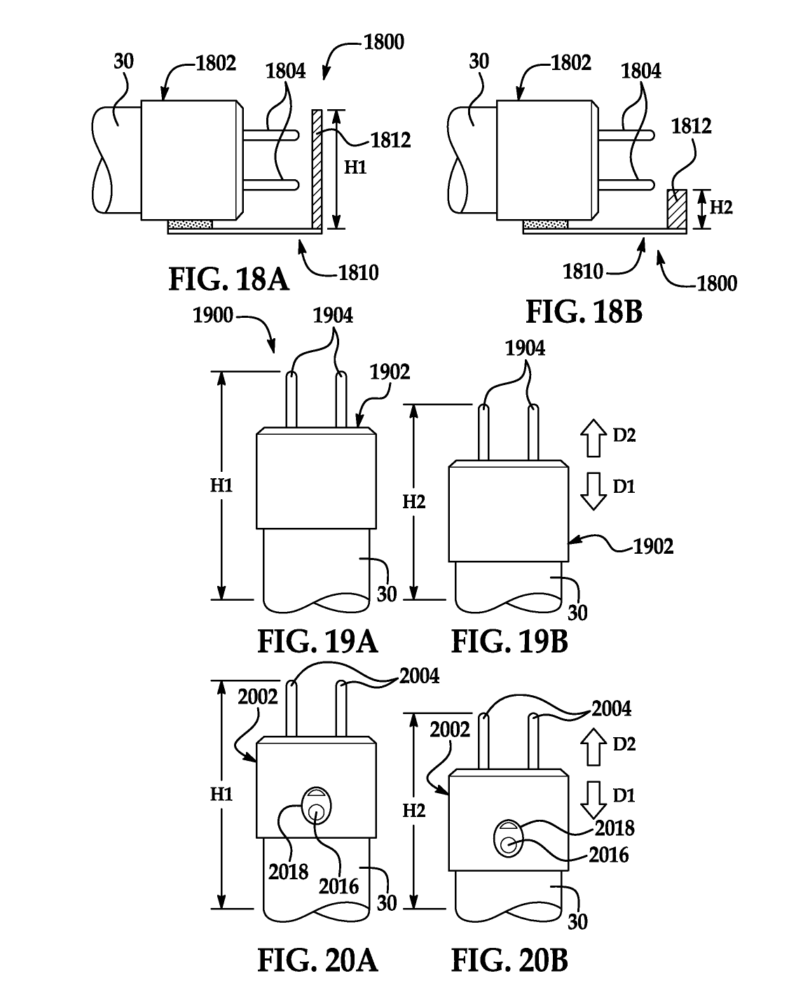

FIGS. 18A and 18B illustrate a light 1800 in accordance with an eighteenth embodiment of the present invention. The light 1800 can include, similar to the sixteenth and seventeenth embodiments, two end caps 1802 (only one end cap shown in FIGS. 18A-18B). Each end cap 1802 can have two pins 1804 extending therethrough and a covering assembly 1810. The light 1800 includes a feature similar to the sixteenth and seventeenth embodiments where the covering assembly 1810 exposes the pins 1804 when the light 1800 is installed. However, unlike the sixteenth and seventeenth embodiments, the covering assembly 1810 includes a cover 1812 that can expand and contract to different heights, thereby exposing the pins 1804. The cover 1812 can be constructed from a resilient insulating material. Alternatively, the cover 1812 can include a biasing member that is integrated with the cover 1812.

Referring the FIG. 18A, before contacting the light fixture, the cover 1812 covers the pins 1804 by remaining expanded at a first height H1. As the light 1800 is placed into the fixture, the cover 1812 makes contact with the fixture, thereby contracting the cover 1812 from the first height H1 to a second, smaller height H2 that is illustrated in FIG. 18B. When the cover 1812 is at the second height H2, the pins 1604 are exposed. Once the pins 1804 are exposed, the pins 1804 can be in electrical communication with the lighting fixture. The lighting fixture can hold the cover 1812 in place at the second height H2 to keep the pins 1804 exposed. Similarly, when the installer wants to remove the light tube 1800, the cover 1812 expands back to the first height H1, as the lighting fixture no longer holds the cover 1812 in place.

FIGS. 19A and 19B illustrate a light 1900 in accordance with a nineteenth embodiment of the present invention. The light 1900 can include two end caps 1902 (only one end cap shown in FIGS. 19A-19B) with each end cap 1902 carrying two pins 1904. One or more of the end caps 1902 can be attached to a spring or other type of biasing mechanism (not shown) located within the housing 30. The end caps 1902 of the light 1900 are biased outwardly, in the second direction D2, where the light 1900 includes a first height H1. When biased the end caps 1902 are outwardly, an open circuit condition exists within the internal circuitry of the tube 30 (not shown), an electrical connection does not exist. As a result, current does not flow to the pins 1904, thereby reducing or removing the risk of shock to the installer.

As the installer installs one of the ends of the light 1900 into the fixture, the force exerted by pressing the respective end of the light tube 1900 into the fixture actuates one or both of the end caps 1902 in the first direction D1, which axially retracts the end caps 1902 to a smaller second height H2, and is illustrated in FIG. 19B. As the end cap 1902 moves inwardly in towards the first direction D1, the pins 1904 electrically connect with the internal circuitry located within the tube 30, and the electrical circuit is closed, thereby allowing current to flow to the pins 1904. Once the light 1900 is removed from the lighting fixture, the end caps 1902 spring back by the force exerted by the biasing mechanism located within the housing 30 towards the second direction D2, and current can no longer flows to the pins 1904.

FIGS. 20A and 20B illustrate a light 2000 in accordance with a twentieth embodiment of the present invention. The light 2000 can include, similar to the nineteenth embodiment, two end caps 2002 (only one end cap shown in FIGS. 20A-20B) with each end cap 2002 carrying two pins 2004. Like the nineteenth embodiment, the end caps 2002 of the light 2000 are biased outwardly, in the second direction D2, where the light 2000 includes the first height H1. The end caps 2002 can be compressed in the first direction D1 to the second height H2, where an electrical connection is established between the pins 2004 and internal circuitry located within the tube 30 to allow current to flow to the pins 2004. However, unlike the nineteenth embodiment, a manual locking slide 2016 is included and is slidable within a groove 2018. The slide 2016 locks the biasing mechanism located within the tube 30 (not shown) in place when the light 2000 is in the open circuit condition and includes the first height H1. When locked by the slide 2016, the end caps 2002 are unable to move in the first direction D1 to deliver current to the pins 2004 unless the installer manually unlocks the slide 2016.

The installer first moves the slide 2016 within the groove 2018, thereby unlocking the biasing mechanism and allowing the end caps 2002 to actuate from the first height H1 to the second height H2. The installer then places the ends of the light tube 2000 into the lighting fixture, where the force exerted by pressing the respective end of the light tube 2000 into the fixture urges one or both of the end caps 2002 in the first direction D1, and the pins 2004 electrically connect with the internal circuitry located within the tube 30. In alternative embodiments, a button, knob or other suitable device can be used in lieu of slide 2016.

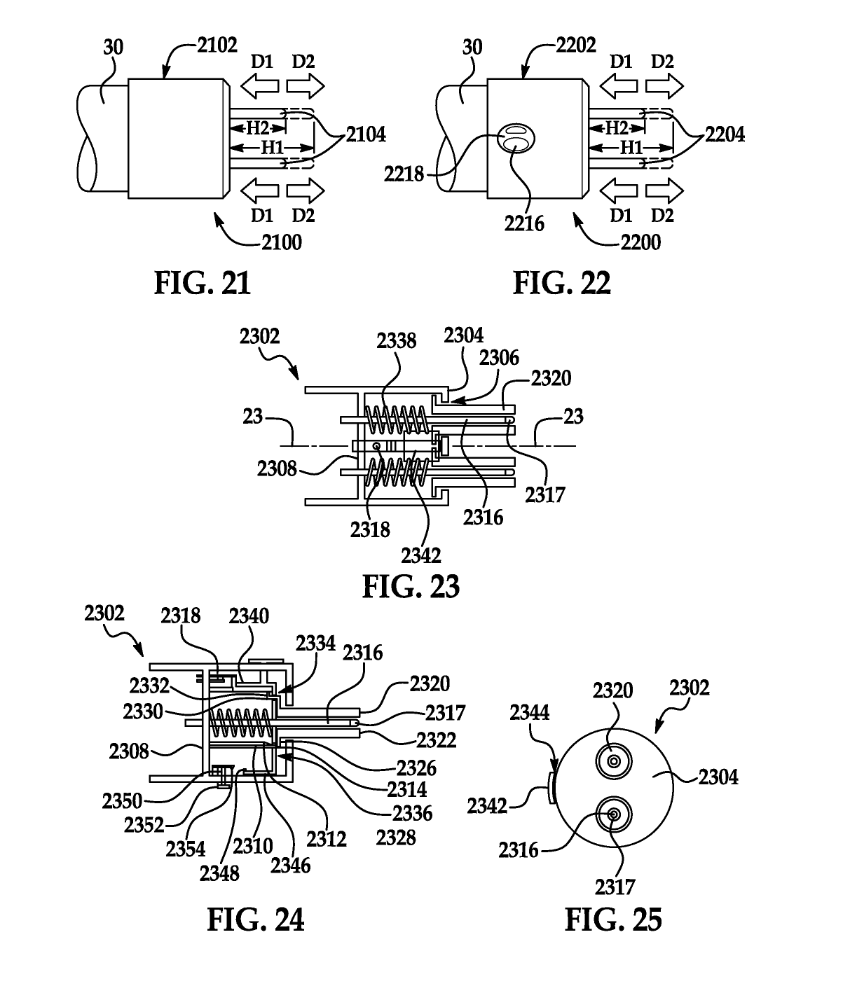

FIG. 21 illustrates a light 2100 in accordance with a twenty-first embodiment of the present invention. The light 2100 can include two end caps 2102 (only one end cap shown in FIG. 21) with each end cap 2102 carrying two pins 2104. Unlike the nineteenth and twentieth embodiments, one or both of the pins 2104, instead of the end caps 2102, can be actuated to close an electrical circuit. The pins 2104 can be attached to a spring or other type of biasing mechanism (not shown) located within the end cap 2102. The pins 2104 of the light 2100 are biased outwardly, towards the second direction D2, where the pins 2104 include a first height H1. When biased outwardly, the pins 2104 do not electrically connect to the internal circuitry in the tube 30, and an open circuit condition exists. As a result, current does not flow to the pins 2104, thereby reducing or removing the risk of shock to the installer.

As the installer installs one of the ends of the light tube 2100 into the fixture, the force exerted by pressing the respective end of the light tube 2100 into the fixture actuates one or both of the pins 2104 in the first direction D1, and axially retracts the pins 2104 into a smaller second height H2. When moved inwardly towards the first direction D1, the pins 2104 electrically connect with the internal circuitry located within the tube 30. The electrical circuit is closed, thereby allowing current to flow to the pins 2104.

FIG. 22 illustrates a light 2200 in accordance with a twenty-second embodiment of the present invention. The light 2200 can include, similar to the twenty-first embodiment, two end caps 2202 (only one end cap shown in FIG. 22) with each end cap 2202 carrying two pins 2204. Like the twenty-first embodiment, the pins 2204 of the light 2200 are biased outwardly, in the second direction D2, where the pins 2204 include the first height H1. The pins 2204 can be compressed inwardly towards the first direction D1 to the second height H2, where an electrical connection is established between the pins 2204 and internal circuitry located within the tube 30 to allow current to flow to the pins 2204. However, unlike the twenty-first embodiment, a manual locking slide 2216 is included and is slidable within a groove 2218. The slide 2216 locks the biasing mechanism located within the tube 30 (not shown) in place when the light 2200 is in the open circuit condition and includes the first height H1. When locked by the slide 2216, the pins 2204 are unable to move in the first direction D1 unless the installer manually unlocks the slide 2016.

The installer first moves the slide 2216 within the groove 2218, thereby unlocking the biasing mechanism and allowing the pins 2204 to actuate from the first height H1 to the second height H2. The installer then places the ends of the light tube 2200 into the lighting fixture, where the force exerted by pressing the respective end of the light tube 2200 into the fixture urges one or both of the pins 2204 in the first direction D1. The pins 2204 can then electrically connect with the internal circuitry located within the tube 30. In alternative embodiments, a button, knob or other suitable device can be used in lieu of slide 2216.

FIGS. 23-25 show an example of an end cap 2302 that can be used as part of an LED-based light in conjunction with, e.g., housing 30, one or more LEDs, and other components. As an example, a pair of the end caps 2302 can be attached to housing 30 of light 100 in place of end caps 102.

Each end cap 2302 can include an outer axial end 2304 defining a pair of apertures 2306, though the end 2304 can define a different number of apertures 2306. Each end cap 2302 can also include a base 2308 spaced axially inward (i.e., toward a center of a light the end cap 2302 is attached to along axis 23-23 as shown in FIG. 23) from the end 2304. A tang 2310 can extend in the axial direction from the base 2308 toward the end 2304. The tang 2310 can include a ramped section 2312 and a distal end 2314 spaced further from the base 2308 than the ramped section 2312, and the distal end 2314 can be flat. The tang 2310 can be flexible and resilient such that it can bend laterally when pressure is applied to the ramped section 2312 in the axial direction and can remain straight if pressure is applied to the distal end 2314 in the axial direction. For example, the tang 2310 can be made from an elastomer.

A pin 2316 can extend through each aperture 2306, and the pins 2316 can be spaced apart, sized, and otherwise configured to engage with a standard fluorescent fixture. Each pin 2316 can be made from an electrically conductive material (e.g., copper, aluminum, or another conductor) and can include a tip 2317 made from an insulating material. While a two pin 2316 and two aperture 2306 configuration can be used for many common fixtures, other numbers of pins 2316 can alternatively be used (e.g., a single pin 2316 configuration). Each pin 2316 can extend through the base 2308 to a side of the base 2308 opposite the end 2304. Alternatively, the pins 2316 can be in electrical connection with components on an opposing side of the base 2316 from the end 2304 without extending therethrough, such as by being connected to wires that pass across the base 2308.

One or more of the pins 2316 can be electrically connected to a pair of switch contacts 2318, which are fixed to the base 2308 in the example shown in FIGS. 23-25 but can be located elsewhere in the end cap 2302 or light which the end cap 2302 is a part of. The switch contacts 2318 can move between an open position in which an electric circuit including one or more of the pins 2316 is open and a closed position in which the electric circuit including the one or more pins 2316 is closed. The switch contacts 2318 can include a spring or other biasing member that urges the switch contacts 2318 to the closed position as a default position when no other force is applied. Insulating sleeves 2320 can be formed of a high-dielectric material such as a thermoplastic. The insulating sleeves 2320 can include cylindrical shapes with an annular cross-section sized to fit around respective pins 2316. The insulating sleeves 2320 can be slidably arranged about respective pins 2316. The length of the insulating sleeves 2320 can be such that distal ends 2322 of the sleeves 2320 extend axially at least as far as the insulating tips 2317 of the pins 2316 relative to end 2304 when the sleeves 2320 are in a pin-protecting position discussed in greater detail below. One or more of the sleeves 2320 can define a flange 2326 that extends radially outward relative to its sleeve 2320, and at least a portion of the flange 2326 can be axially aligned with the flat distal end 2314 of the tang 2310.

The insulating sleeves 2320 can be connected to a platform 2328. The connection can include an extension 2330 portion of the sleeves 2320 having a tab 2332, and the extension 2330 can pass through an aperture 2334 in the platform 2328 such that the tab 2332 is on an opposing side of the platform 2328 from the sleeves 2320. The length of the extension 2330 along axis 23-23 can be as long as or longer than the distance between the distal end 2314 and the ramped section 2312 of the tang 2310.

The platform 2328 can be slidably arranged in the end cap 2302 between the end 2304 and the base 2308. The platform 2328 can define a slot 2336. One end of the slot 2336 can be axially aligned with an end of the ramped section 2312 of the tang 2310 such that the slot 2336 overlays the distal end 2314 of the tang 2310 but not its ramped section 2312. Additionally, the flange 2326 of the insulating sleeves 2320 can extend a portion of the distance across the slot 2336. An opposing end of the slot 2336 can be further radially outward than the flange 2326. One or more biasing members, such as the illustrated springs 2338 positioned around respective pins 2316, can bias the platform 2328 toward the end 2304.

A sliding actuator 2340 can be joined to or formed integrally with the platform 2328. The sliding actuator 2340 can include a knob 2342 extending to an exterior of the end cap 2302 and slidable along a slot 2344 defined by the end cap 2302. The knob 2342 can thus be accessible to, e.g., an installer of a light including the end cap 2302. The knob 2342 can include a knurled surface to enhance an installer's grip. The sliding actuator 2340 can be positioned relative to the switch contacts 2318 such that when the knob 2342 is urged along the slot 2344 a predetermined distance toward the platform 2328, the sliding actuator 2340 contacts the switch contacts 2318 and urges the switch contacts 2318 into the open position.

A latch receiver 2346 can also be joined to or formed integrally with the platform 2328. The latch receiver 2346 can include a protuberance 2348 spaced from the platform 2328. Alternatively, instead of the protuberance 2348, the latch receiver 2346 can include another structure that can be selectively engaged, such as an aperture.

The end cap 2302 can include a latch 2350. The latch 2350 can define a release button 2352 extending to an exterior of the end cap 2302 and a chamfered hook 2354 on the interior of the end cap 2302. The latch 2350 can be moveable between a resting position and an actuated position. The latch 2350 can also include a biasing member, e.g., a spring, that biases the latch 2350 toward the resting position. The latch 2350 can be positioned such that the chamfered hook 2354 engages the protuberance 2348 of the latch receiver 2346 when the latch receiver 2346 is urged a predetermined distance toward the base 2308. The chamfered hook 2354 can have a generally triangular shape or another shape that allows the protuberance 2348 of the latch receiver 2346 to pass in one direction and to prevent the latch receiver 2346 from moving in an opposing direction. Actuation of the release button 2352 can bias the latch 2350 such that the chamfered hook 2354 disengages the protuberance 2348.

When a light including the end caps 2302 is not installed in a fixture, the insulating sleeves 2320 can be in the pin-protecting position. For example, when a light including the end caps 2302 is purchased the insulating sleeves 2320 can come in the pin-protecting position. With the insulating sleeves 2320 in the pin-protecting position, the insulating sleeves 2320 are fully extended and protect the pins 2316. Additionally, the tang 2310 contacts the flange 2326, thereby hindering movement of the insulating sleeves 2320 away from the pin-protecting position.

Also with the insulating sleeves 2320 in the pin-protecting position, the sliding actuator 2340 is not engaged with the switch contacts 2318, which remain in the closed position. However, since the insulating sleeves 2320 protect the pins 2316 in the pin-protecting position, the risk of an electrical shock is reduced or eliminated with the insulating sleeves 2320 in the pin-protecting position even though the switch contacts 2318 are in the closed position. Further, installation of a light including the end caps 2302 would be difficult or not possible with the insulating sleeves 2320 in the pin-protecting position because the light would not likely fit into a fixture with the insulating sleeves 2320 fully protracted to the pin-protecting position. Also with the insulating sleeves 2320 in the pin-protecting position the latch receiver 2346 is spaced from and not engaged with the latch 2350.

Prior to installing a light including the end caps 2302 in a fixture, an installer can move the insulating sleeves 2320 from the pin-protecting position to a pin-exposing position by urging the knob 2342 away from the end 2304. As the knob 2342 is initially urged away from the end 2304, the insulating sleeves 2320 do not move because the tab 2332 of the sleeves 2320 is spaced from the platform 2328 by the length of the extension 2330. However, the initial movement of the knob 2342 moves the platform 2328 relative to the tang 2310, and the distal end 2314 of the tang 2310 passes through the slot 2336 in the platform 2328. The platform 2328 then contacts the ramped section 2312 of the tang 2310. Due to the angle of the ramped section 2312, the platform 2328 urges the tang 2310 laterally through the slot 2336 in the platform 2336, bending the tang 2310. With the tang 2310 bent, the distal end 2314 of the tang 2310 no longer contacts the flange 2326 of the insulating sleeves 2320.

After the knob 2342 moves the length of the extension 2330 of the insulating sleeves 2320, the sliding actuator 2340 contacts the tab 2332 of the insulating sleeves 2320. Once the sliding actuator 2340 contacts the tab 2332, additional movement of the knob 2342 toward the base 2308 moves the insulating sleeves 2320. Thus, the insulating sleeves 2320 are not prevented by the tang 2310 from moving toward the base 2308.

As mentioned above, when the knob 2342 is moved a predetermined distance, the sliding actuator 2340 engages the switch contacts 2318 and biases the switch contacts 2318 to their open position. With the switch contacts 2318 in their open position, the electric circuit including the pins 2316 is open. As a result, current would not flow through the pins 2316 even if a current were applied to the pins 2316, such as if the light were installed in the fixture. Since current does not flow through the pins 2316 when the insulating sleeves 2320 are in the pin-exposing position, the risk of shock to an installer is reduced or eliminated.

Also when the insulating sleeves 2320 are in the pin-exposing position, the latch 2350 can engage the latch receiver 2346. As a result, even though the springs 2338 urge the insulating sleeves 2320 from the pin-exposing position to the pin-protecting position by applying a force to the platform 2328, the engagement between the latch 2350 and latch receiver 2346 can retain the insulating sleeves 2320 in the pin-exposing position. By retaining the insulating sleeves 2320 in the pin-exposing position, the switch contacts 2318 are retained in the open position and the risk of shock remains reduced or eliminated.

With the insulating sleeves 2320 in the pin-exposing position, the installer can position the light including the end caps 2302 in the fixture. Since the switch contacts 2318 remain in the open position, current does not flow through the pins 2316. Once the light is in the fixture, the installer can actuate the release button 2352. Actuation of the release button 2352 can eliminate the engagement between the latch 2350 and latch receiver 2346, which in turn can allow the springs 2338 to bias the platform 2328 toward the end 2304. Movement of the platform 2328 toward the end 2304 also moves the sliding actuator 2340, which can allow the switch contacts 2318 to return to the closed position. The insulating sleeves 2320 can move toward the pin-protecting position, although the fixture that the light is now installed in can prevent the sleeves 2320 from reaching the pin-protecting position. As such, the pins 2316 can remain partially exposed. Thus, the pins 2316 can be electrically connected to the fixture and, since the switch contacts 2318 are in the closed position, to other components in the light such as LEDs.

Upon removal of the light from the fixture, the springs 2338 urge the insulating sleeves 2320 back to the pin-protecting position. Thus, the end caps 2302 can reduce or eliminate the shock risk associated with LED-based lights prior to installation, during installation, after installation, and upon removal. In alternative examples, the end cap 2302 can include other features. For example, a note can be included on the end cap 2302 behind the knob 2342 when the insulating sleeves 2320 are in the pin-protecting position that becomes visible when the knob 2342 is moved toward the base 2308 and that alerts an installer to press the release button 2352 after installing the light. Also in alternative examples, the end cap 2302 need not include certain features, such as the tang 2310 and/or the latch 2350 and latch receiver 2346.

The above-described embodiments have been described in order to allow easy understanding of the invention and do not limit the invention. On the contrary, the invention is intended to cover various modifications and equivalent arrangements included within the scope of the appended claims, which scope is to be accorded the broadest interpretation so as to encompass all such modifications and equivalent structure as is permitted under the law.

What is claimed is:

1. An LED-based light for replacing a fluorescent bulb in a conventional fluorescent light fixture comprising:
a housing having a first end opposing a second end;
a circuit board disposed within the housing and extending along a longitudinal axis of the housing;
at least one LED mounted to the circuit board;
at least one end cap disposed on one of the first and second ends of the housing, the end cap including a switch and at least one electrically conductive pin configured for physical and electrical connection to the light fixture; and
circuitry configured to provide a current path between the at least one LED and the at least one electrically conductive pin, wherein the switch is configured to selectively disconnect the current path.

2. The LED-based light of claim 1, wherein the at least one end cap includes a first end cap and a second end cap, wherein the first end cap is disposed on the first end of the housing and the second end cap is disposed on the second end of the housing, wherein the second end cap includes at least one electrically conductive pin configured for physical and electrical connection to the light fixture, and wherein the current path includes the at least one LED and is formed between the first and the second end caps.

3. The LED-based light of claim 1, wherein the switch is selectively engageable between a first and at least a second position, the switch configured to create an open circuit condition in the current path in the first position and create a closed circuit condition in the current path in the second position.

4. The LED-based light of claim 3, further comprising:
a circumferentially extending collar, wherein the switch is engageable between the first and second positions by rotation of the collar about the longitudinal axis of the housing.

5. The LED-based light of claim 4 wherein the collar is included in and rotatable about the end cap.

6. The LED-based light of claim 3, wherein the switch is engageable between the first and second positions by rotation of the end cap about the longitudinal axis of the housing.

7. The LED-based light of claim 3, further comprising a moveable pin adjacent to the electrically conductive pin and extending parallel to the longitudinal axis of the housing through an aperture defined by the end cap, wherein:
the moveable pin is configured for travel along the longitudinal axis of the housing between a protracted position and a retracted position and configured to create an open circuit condition in the current path in the protracted position and create a closed circuit condition in the current path in the retracted position.

8. The LED-based light of claim 7, wherein the moveable pin is configured for travel along the longitudinal axis of the housing between the protracted position and the retracted position in response to an axial force applied to the moveable pin, further comprising:
a spring biasing mechanism configured to urge the moveable pin toward the protracted position.

9. The LED-based light of claim 7, further comprising a circumferentially extending collar, wherein:
the switch is engageable between the first and second positions by rotation of the collar about the longitudinal axis of the housing; and
the moveable pin is configured for travel between the protracted position and the retracted position in response to the rotation of the collar such that the moveable pin travels from the protracted position to the retracted position as the switch is engaged from the first position to the second position.

10. The LED-based light of claim 7, wherein the moveable pin has a generally triangular profile.

11. The LED-based light of claim 3, further comprising:
a pin cover configured for travel between a protracted position and a retracted position, the pin cover configured to substantially enclose the electrically conductive pin in the protracted position and to expose the electrically conductive pin in the retracted position.

12. The LED-based light of claim 11, wherein the switch is coupled to the pin cover and configured for engagement between the first and second positions in response to travel of the pin cover such that the switch is engaged in the second position when the pin cover is in the protracted position and is engaged in the first position as the pin cover travels from the protracted position to the retracted position.

13. The LED-based light of claim 12, further comprising:
a latch configured to releasably secure the pin cover when the switch is engaged in the first position; and
a biasing mechanism configured to urge the pin cover toward the protracted position.

14. The LED-based light of claim 11, wherein the pin cover comprises an insulating sleeve concentric with the electrically conductive pin.

15. The LED-based light of claim 3, wherein:
the electrically conductive pin is configured for travel along the longitudinal axis of the housing between a protracted position and a retracted position in response to an axial force applied to the electrically conductive pin, the electrically conductive pin extending from the end cap a first distance in the protracted position and a second distance less than the first distance in the retracted position; and
the switch is engageable between the first and second positions in response to travel of the electrically conductive pin between the protracted position and the retracted position such that the switch is engaged in the first position when the electrically conductive pin is in the protracted position and engaged in the second position when the electrically conductive pin is in the retracted position.

16. The LED-based light of claim 15, further comprising:
a spring biasing mechanism configured to urge the electrically conductive pin toward the protracted position, the spring biasing mechanism including a locking mechanism to selectively permit retraction of the electrically conductive pin.

17. The LED-based light of claim 3, wherein:
the electrically conductive pin is rotatable about an axis perpendicular to the longitudinal axis of the housing; and
the switch is engageable between the first and second positions by rotation of the electrically conductive pin.

18. The LED-based light of claim 17, wherein the switch is configured for engagement in the first position when the pin extends from the end cap parallel to the longitudinal axis of the housing and configured for engagement in the second position when the pin extends at a predetermined angle to the longitudinal axis of the housing.

19. The LED-based light of claim 18, wherein the predetermined angle is between approximately 15° and 30°.

20. The LED-based light of claim 3, wherein:
the end cap is configured for travel along the longitudinal axis of the housing between a protracted position and a retracted position; and
the switch is engageable between the first and second positions in response to travel of the end cap between the protracted position and the retracted position such that the switch is engaged in the first position when the end cap is in the protracted position and engaged in the second position when the end cap is in the retracted position.

21. The LED-based light of claim 20, further comprising:
a spring biasing mechanism configured to urge the end cap toward the protracted position, the spring biasing mechanism including a locking mechanism to selectively permit retraction of the end cap.

22. The LED-based light of claim 3, wherein the switch is one of a manual slide switch, a push button switch and a toggle switch.

23. The LED-based light of claim 3, further comprising:
means for retaining the switch in the second position.

24. An LED-based light for replacing a fluorescent bulb in a conventional fluorescent light fixture comprising:
a housing having a first end opposing a second end;
a circuit board disposed within the housing and extending along a longitudinal axis of the housing;
at least one LED mounted to the circuit board;
at least one end cap disposed on one of the first and second ends of the housing, the end cap including at least one electrically conductive pin configured for physical and electrical connection to the light fixture; and
a pin cover composed of an insulating material adjacent to the first end and configured to selectively expose and substantially enclose the electrically conductive pin.

25. The LED-based light of claim 24, wherein:
at least a portion of the end cap comprises the pin cover and defines an aperture axially aligned with the electrically conductive pin; and
the electrically conductive pin is configured for travel along the longitudinal axis of the housing between a protracted position and a retracted position such that the electrically conductive pin extends through the end cap in the protracted position and is substantially enclosed within the end cap in the retracted position.

26. The LED-based light of claim 25, further comprising:
a slide lever coupled to the electrically conductive pin, wherein the electrically conductive pin is configured for travel between the protracted position and the retracted position in response to an axial force applied to the slide lever.

27. The LED-based light of claim 25, further comprising a circumferentially extending collar, wherein the electrically conductive pin is configured for travel between the protracted position and the retracted position in response to rotation of the collar about the longitudinal axis of the housing.

28. The LED-based light of claim 27, wherein the collar is included in and rotatable about the end cap.

29. The LED-based light of claim 24, wherein the pin cover is configured for travel between a protracted position and a retracted position, the pin cover substantially enclosing the electrically conductive pin in the protracted position exposing the electrically conductive pin in the retracted position.

30. The LED-based light of claim 29, wherein the pin cover comprises an insulating sleeve concentric with the electrically conductive pin.

31. The LED-based light of claim 30, wherein the pin cover is composed of a resilient material and configured to compress into the retracted position in response to an axial force applied to the pin cover and to decompress to the protracted position in the absence of an axial force applied to the pin cover.

32. The LED-based light of claim 29, wherein the pin cover is concentric with the end cap and defines an aperture aligned with the electrically conductive pin, with at least a portion of the pin cover retracting into the end cap in the retracted position.

33. The LED-based light of claim 29, wherein the pin cover is configured for travel between the protracted position and the retracted position in response to an axial force applied to the pin cover.

34. The LED-based light of claim 33, further comprising a slide lever coupled to the pin cover, wherein the pin cover is configured for travel between the protracted position and the retracted position in response to an axial force applied to the pin cover through the slide lever.

35. The LED-based light of claim 34, wherein:
the slide lever is slidably engaged within an axial groove defined by the end cap; and
the slide lever includes a locking mechanism configured to selectively permit retraction of the pin cover.

36. The LED-based light of claim 29, further comprising:
a spring biasing mechanism configured to urge the pin cover toward the protracted position.

37. The LED-based light of claim 29, wherein the pin cover is coupled to the end cap and is rotatable between the protracted position and the retracted position about an axis perpendicular to the longitudinal axis of the housing.

38. The LED-based light of claim 37, further comprising:
a spring biasing connecting member coupling the pin cover to the end cap, the spring biasing connecting member configured to urge the pin cover toward the protracted position.

39. The LED-based light of claim 37, wherein:
the pin cover is composed of a resilient material biased to urge the pin cover toward the protracted position; and
the pin cover is slidably coupled to the end cap and further configured for travel along the longitudinal axis of the housing.

40. The LED-based light of claim 29, wherein the pin cover is resiliently extendable between the protracted position and retracted positions in a radial direction along an axis perpendicular to the longitudinal axis of the housing.

41. A method of installing an LED-based light into a conventional fluorescent light fixture, the LED-based light including a housing having a first end opposing a second end, at least one LED disposed within the housing, a first end cap disposed on the first end of the housing including at least one electrically conductive pin, a second end cap disposed on the second end of the housing including at least one electrically conductive pin, circuitry providing a current path between the first and second end cap's electrically conductive pins, and a switch, the method comprising:
engaging the switch in a first position to disconnect a current path provided by the circuitry;
positioning the first and second end cap's at least one electrically conductive pin into the light fixture; and
engaging the switch in a second position to connect the current path.

42. The method of claim 41, wherein a pin cover composed of an insulating material is adjacent to at least the first end and configured to selectively expose and substantially enclose the first end cap's at least one electrically conductive pin in response to a force applied to the pin cover, the step positioning the first and second end cap's at least one electrically conductive pin into the light fixture further comprising:
applying a force to the pin cover such that the pin cover is retracted to expose the first end cap's at least one electrically conductive pin by pressing the pin cover against the fixture.
